(19) United States
(12) Patent Application Publication
(10) Pub. No.: US 2018/0260345 A1
(43) Pub. Date: Sep. 13, 2018

(54) MEMORY MODULE AND MEMORY SYSTEM INCLUDING THE SAME

(71) Applicant: SK hynix Inc., Gyeonggi-do (KR)

(72) Inventor: Jong-Ho JUNG, Gyeonggi-do (KR)

(21) Appl. No.: 15/725,934

(22) Filed: Oct. 5, 2017

(30) Foreign Application Priority Data
Mar. 7, 2017 (KR) 10-2017-0028642

(51) Int. Cl. G06F 13/16; G11C 7/22; G11C 7/10

(52) U.S. Cl. CPC G06F 13/1689; G11C 7/1024; G11C 7/22; G06F 13/1673

(57) ABSTRACT

A memory module includes: a plurality of memory devices; a plurality of data buffers suitable for receiving a write data transferred from a memory controller, and transferring a read data to the memory controller; and a module controller suitable for:

controlling the plurality of the memory devices and the plurality of the data buffers under a control of the memory controller; and, during a read operation, transferring one or more control signals to the plurality of the data buffers through a buffer communication bus after delaying the control signals by a difference between a first column address strobe (CAS) latency value, which is a set value of the memory module, and a second CAS latency value, which is a set value of the plurality of the data buffers.

### CROSS-REFERENCE TO RELATED APPLICATIONS

The present application claims priority of Korean Patent Application No. 10-2017-0028642, filed on Mar. 7, 2017, which is incorporated herein by reference in its entirety.

### BACKGROUND

### 1. Field

Exemplary embodiments of the present invention relate to a memory module and a memory system including the memory module.

### 2. Description of the Related Art

As mobile communication terminals, such as a smart phone and a tablet personal computer (PC) are widely used and the use of a social network service (SNS), a machine-to-machine (M2M) network, and a sensor network proliferates, the amount, generation speed and diversity of data increase by geometric progression. To process big data, not only the speed of a memory but also the capacity of a memory device and the capacity of a memory module including the memory device are important.

When a dual in-line memory module (DIMM) type memory module, which is used as a system memory at present, is fabricated to have a large capacity, the number of memory devices that are included in the memory module is increased. As a result, the operational load is raised and it becomes difficult to route signals using the limited channels, thus, increasing the latency of the memory devices. Therefore, it is required to develop technology to cope with the increasing latency.

### SUMMARY

Embodiments of the present invention are directed to a memory module capable of performing an operation with a long latency.

In accordance with an embodiment of the present invention, a memory module includes: a plurality of memory devices; a plurality of data buffers suitable for receiving a write data transferred from a memory controller, and transferring a read data to the memory controller; and a module controller suitable for: controlling the plurality of the memory devices and the plurality of the data buffers under a control of the memory controller; and, during a read operation, transferring one or more control signals to the plurality of the data buffers through a buffer communication bus after delaying the control signals by a difference between a first column address strobe (CAS) latency value, which is a set value of the memory module, and a second CAS latency value, which is a set value of the plurality of the data buffers.

The module controller may transfer a command, an address, and a clock, which are transferred from the memory controller, to the plurality of the memory devices, and the module controller generates an error correction code based on the write data that is transferred from the plurality of the data buffers, transfers the write data and the error correction code to the plurality of the memory devices, corrects an error of the read data which is read from the plurality of the memory devices based on the error correction code which is read from the plurality of the memory devices to produce an error-corrected read data, and transfers the error-corrected read data to the plurality of the data buffers.

The module controller may include: a command decoding unit suitable for decoding a command which is transferred from the memory controller to produce a decoding result; a control signal generation unit suitable for transforming the decoding result of the command decoding unit into the control signals; and a latency control circuit suitable for, during the read operation, delaying a moment when the control signals are transferred through the buffer communication bus by the difference between the first CAS latency value and the second CAS latency value.

The latency control circuit may include: a delayer; and a delay setter suitable for setting a delay value of the delayer to the difference between the first CAS latency value and the second CAS latency value during the read operation, and setting the delay value of the delayer to ‘0’ during an operation except for the read operation.

The command decoding unit may further decode some bits of an address which is transferred from the memory controller.

The module controller may include: an error correction code generation circuit suitable for generating an error correction code based on the write data which is transferred from the plurality of the data buffers; and an error correction circuit suitable for correcting an error of the read data which is read from the plurality of the memory devices based on the error correction code which is read from the plurality of the memory devices.

When the memory controller transfers a command and an address for setting a CAS latency to the module controller, a CAS latency of the memory module may be set to the first CAS latency value and a CAS latency of the plurality of the data buffers may be set to the second CAS latency value, which is different from the first CAS latency value.

Each of the plurality of the memory devices may be a dynamic random access memory (DRAM), and the memory module may be of a dual in-line memory module (DIMM) type.

In accordance with another embodiment of the present invention, a memory system includes: a memory module; and a memory controller suitable for transferring a command, an address, and a write data to the memory module, and receiving a read data from the memory module, wherein the memory module comprises:
a plurality of memory devices; a plurality of data buffers suitable for receiving the write data from the memory controller, and transferring the read data to the memory controller; and a module controller suitable for: controlling the plurality of the memory devices and the plurality of the data buffers under a control of the memory controller, and, during a read operation, transferring one or more control signals to the plurality of the data buffers through a buffer communication bus after delaying the control signals by a difference between a first column address strobe (CAS) latency value, which is a set value of the memory module, and a second CAS latency value, which is a set value of the plurality of the data buffers.

The module controller may transfer the command, the address, and a clock, which are transferred from the memory controller, to the plurality of the memory devices, and the module controller may generate an error correction code based on the write data that is transferred from the plurality of the data buffers, transfer the write data and the error correction code to the plurality of the memory devices, correct an error of the read data which is read from the plurality of the memory devices based on the error correction code which is read from the plurality of the memory devices to produce an error-corrected read data, and transfer the error-corrected read data to the plurality of the data buffers.

The module controller may include: a command decoding unit suitable for decoding the command to produce a decoding result; a control signal generation unit suitable for transforming the decoding result of the command decoding unit into the control signals; and a latency control circuit suitable for, during the read operation, delaying a moment when the control signals are transferred through the buffer communication bus by the difference between the first CAS latency value and the second CAS latency value.

The latency control circuit may include: a delayer; and a delay setter suitable for setting a delay value of the delayer to the difference between the first CAS latency value and the second CAS latency value during the read operation, and setting the delay value of the delayer to ‘0’ during an operation except for the read operation.

The command decoding unit may further decode some bits of the address.

The module controller may include: an error correction code generation circuit suitable for generating an error correction code based on the write data which is transferred from the plurality of the data buffers; and an error correction circuit suitable for correcting an error of the read data which is read from the plurality of the memory devices based on the error correction code which is read from the plurality of the memory devices.

When the memory controller transfers the command and the address for setting a CAS latency to the module controller, a CAS latency of the memory module may be set to the first CAS latency value and a CAS latency of the plurality of the data buffers may be set to the second CAS latency value, which is different from the first CAS latency value.

Each of the plurality of the memory devices may be a dynamic random access memory (DRAM), and the memory module may be of a dual in-line memory module (DIMM) type.

### BRIEF DESCRIPTION OF THE DRAWINGS

FIG. 1 is a block diagram illustrating a memory module in accordance with an embodiment of the present invention.

FIG. 2 is a block diagram illustrating a memory module in accordance with another embodiment of the present invention.

FIG. 3 is a block diagram illustrating a module controller shown in FIG. 2.

FIG. 4 is a table showing an operation of a latency control circuit shown in FIG. 3.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

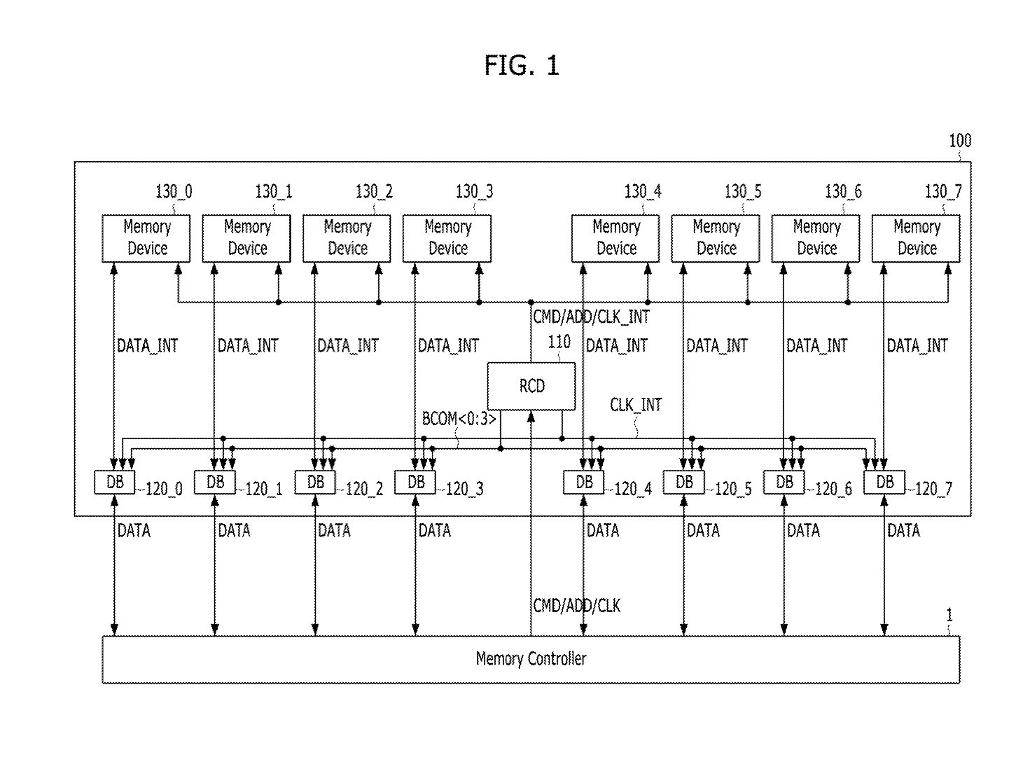

FIG. 1 is a block diagram illustrating a memory module 100 in accordance with an embodiment of the present invention. For the sake of convenience in description, a memory controller 1 serving as a host for controlling the memory module 100 is illustrated together in FIG. 1.

Referring to FIG. 1, the memory module 100 may include a register clock driver (RCD) 110, data buffers 120_0 to 120_7, and memory devices 130_0 to 130_7. The memory module 100 shown in FIG. 1 may be called a Load Reduced Dual In-Line Memory Module (LRDIMM).

The register clock driver 110 may buffer a command CMD, an address ADD, and a clock CLK that are transferred from the memory controller 1, and transfer them to the memory devices 130_0 to 130_7. The register clock driver 110 may provide the clock CLK to the data buffers 120_0 to 120_7. The register clock driver 110 may process the command CMD and the address ADD required by the data buffers 120_0 to 120_7 in a form appropriate for a buffer communication bus BCOM<0:3>, and provide the processed command CMD and address ADD as control signals to the data buffers 120_0 to 120_7 through the buffer communication bus BCOM<0:3>.

During a write operation, the data buffers 120_0 to 120_7 may receive data DATA from the memory controller 1 and transfer the received data DATA to the memory devices 130_0 to 130_7. During a read operation, the data buffers 120_0 to 120_7 may receive data DATA from the memory devices 130_0 to 130_7 and transfer the received data DATA to the memory controller 1. In the memory module 100, the data buffers 120_0 to 120_7 may directly transfer and receive the data DATA to and from the memory controller 1. Therefore, during a write operation, the data buffers 120_0 to 120_7 may receive the data DATA from the memory controller 1 at a moment when a write latency WL passes from a moment when a write command is applied from the memory controller 1, and during a read operation, the data buffers 120_0 to 120_7 may transfer the data DATA to the memory controller 1 at a moment when a column address strobe (CAS) latency CL passes from a moment when a read command is applied from the memory controller 1. For this reason, the data buffers 120_0 to 120_7 may need to set the write latency WL and the CAS latency CL and require information on the moment when the write command is applied and the moment when the read command is applied. The data buffers 120_0 to 120_7 may receive the Information related to setting the latencies and information related to the moments when the write and read commands are applied from the register clock driver 110 through the buffer communication bus BCOM<0:3>.

The memory devices 130_0 to 130_7 may operate by receiving the command CMD, the address ADD, and the clock CLK from the register clock driver 110, and transferring/receiving the data DATA through the data buffers 120_0 to 120_7. Each of the memory devices 130_0 to 130_7 may be a Dynamic Random Access Memory (DRAM), or another kind of a memory.

In FIG. 1, the reference symbol ‘DATA_INT’ represents a bus through which data are transferred in the inside of the memory module 100, and the reference symbol ‘CMD/ADD/CLK_INT’ represents a bus through which a command, an address, and a clock are transferred in the inside of the memory module 100. The reference numeral ‘CLK_INT’ represents a bus through which a clock is transferred in the inside of the memory module 100.

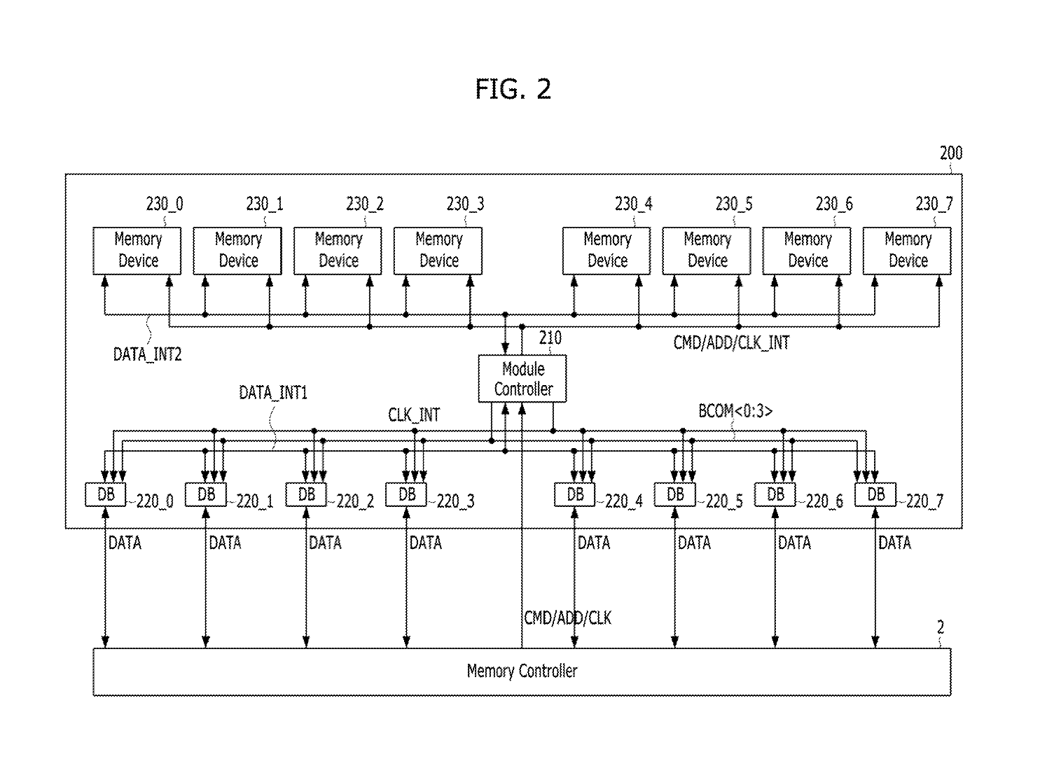

FIG. 2 is a block diagram Illustrating a memory module 200 in accordance with another embodiment of the present invention. For the sake of convenience in description, a memory controller 2 serving as a host for controlling the memory module 200 is illustrated together in FIG. 2.

Referring to FIG. 2, the memory module 200 may include a module controller 210, data buffers 220_0 to 220_7, and memory devices 230_0 to 230_7.

Each of the memory devices 230_0 to 230_7 may have a large capacity. Each of the memory devices 230_0 to 230_7 may include a plurality of memory chips that are stacked one on another. For example, each of the memory devices 230_0 to 230_7 may include 8 memory chips. In this case, the number of the memory chips included in the memory devices 230_0 to 230_7 of the memory module 200 may come to 64. When a plurality of memory chips are stacked in order to increase the capacity of the memory devices 230_0 to 230_7, load may be increased and it becomes difficult to route signals, thus increasing the latency of the memory devices 230_0 to 230_7 and causing many errors in the course of performing a write operation and/or a read operation. Each of the memory devices 230_0 to 230_7 may be one among diverse kinds of memories which include a DRAM, a Resistive Random Access Memory (RRAM), a Phase-change Random Access Memory (PRAM), a Ferroelectric Random Access Memory (FRAM), and a Magnetic Random Access Memory (MRAM).

The module controller 210 may buffer a command CMD, an address ADD, and a clock CLK that are transferred from the memory controller 2, and transfer them to the memory devices 230_0 to 230_7. The module controller 210 may provide the clock CLK to the data buffers 220_0 to 220_7. The module controller 210 may process the command CMD and the address ADD required by the data buffers 220_0 to 220_7 in a form appropriate for a buffer communication bus BCOM<0:3>, and provide the processed command CMD and address ADD as control signals to the data buffers 220_0 to 220_7 through the buffer communication bus BCOM<0:3>. The operation of the module controller 210 described above may be the same as the operation of the register clock driver 110.

Differently from the register clock driver 110, the module controller 210 may transfer data DATA between the data buffers 220_0 to 220_7 and the memory devices 230_0 to 230_7. The module controller 210 may generate an error correction code by using a write data that is transferred from the data buffers 220_0 to 220_7 during a write operation. Also, the module controller 210 may transfer the write data and the error correction code to the memory devices 230_0 to 230_7 so that the write data and the error correction code are written in the memory devices 230_0 to 230_7. During a read operation, the module controller 210 may correct an error of a read data which is read from the memory devices 230_0 to 230_7 based on a corresponding error correction code which is read from the memory devices 230_0 to 230_7, and transfer the error-corrected read data to the data buffers 220_0 to 220_7.

A first Internal data bus DATA_INT1 may be provided between the data buffers 220_0 to 220_7 and the module controller 210, and a second internal data bus DATA_INT2 may be provided between the module controller 210 and the memory devices 230_0 to 230_7. At this time, data may be transferred through the first internal data bus DATA_INT1, and data and an error correction code may be transferred through the second internal data bus DATA_INT2. For example, the first Internal data bus DATA_INT1 may transfer the write data to the module controller 210 from the data buffers 220_0 to 220_7, and transfer the error-corrected read data to the data buffers 220_0 to 220_7 from the module controller 210. Further, the second internal data bus DATA_INT2 may transfer the write data and the error correction code to the memory devices 230_0 to 230_7 from the module controller 210, and transfer the read data and the error correction code to the module controller 210 from the memory devices 230_0 to 230_7.

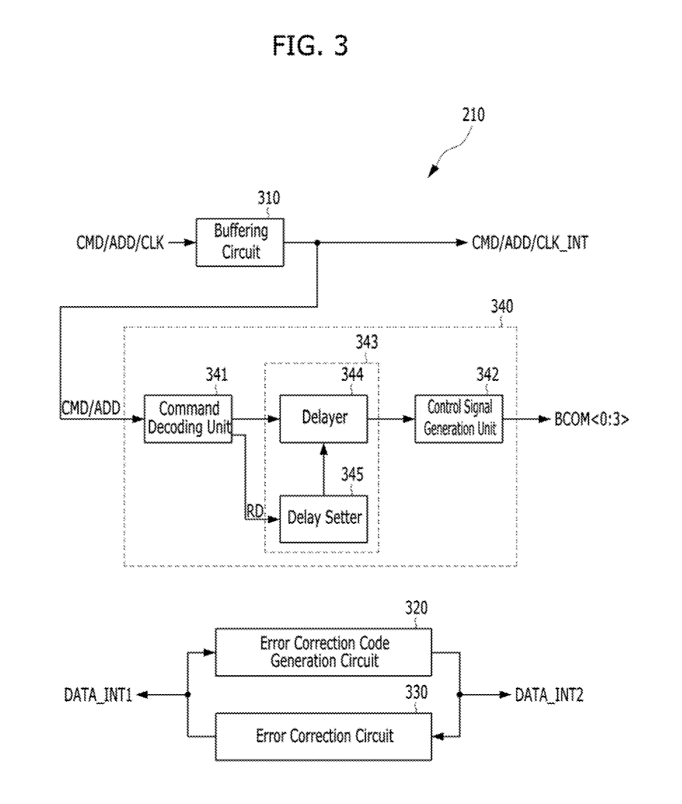

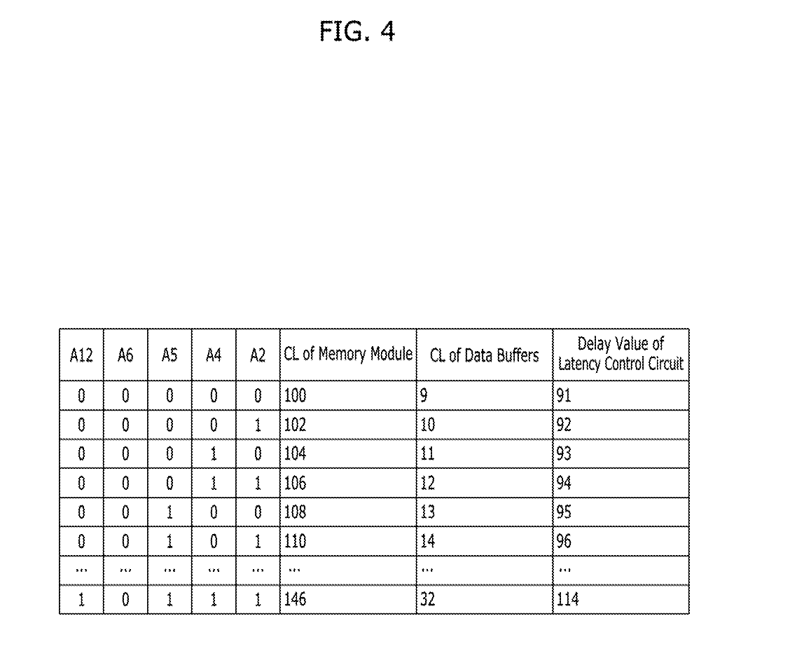

The errors occurring in the memory devices 230_0 to 230_7 may be decreased by an error correction code generation operation and an error correction operation of the module controller 210, and the capacity of the memory devices 230_0 to 230_7 may be increased by stacking a plurality of memory chips in each of the memory devices 230_0 to 230_7. However, the latency of the memory module 200 may be increased further due to the error correction code generation operation and the error correction operation of the module controller 210. The CAS latency CL of the memory module 200 may be increased up to a value of 100 or more, but the data buffers 220_0 to 220_7 may hardly support such a long latency. To address the concern, the module controller 210 may control the control signals over the buffer communication bus BCOM<0:3> so that the data buffers 220_0 to 220_7 may operate with the long CAS latency CL. This will be described in detail later with reference to FIGS. 3 and 4.

During a write operation, the data buffers 220_0 to 220_7 may receive a data DATA from the memory controller 2 and transfer the data DATA to the module controller 210. During a read operation, the data buffers 220_0 to 220_7 may receive a data DATA from the module controller 210 and transfer the data DATA to the memory controller 2. In the memory module 200, the data buffers 220_0 to 220_7 may directly transfer and receive the data DATA to and from the memory controller 2. Therefore, during a write operation, the data buffers 220_0 to 220_7 may receive the data DATA from the memory controller 2 at a moment when a write latency WL passes from a moment when a write command is applied from the memory controller 2, and during a read operation, the data buffers 220_0 to 220_7 may transfer the data DATA to the memory controller 2 at a moment when a CAS latency CL passes from a moment when a read command is applied from the memory controller 2. For this reason, the data buffers 220_0 to 220_7 may need to set the write latency WL and the CAS latency CL and require information on the moment when the write command is applied and the moment when the read command is applied. The data buffers 220_0 to 220_7 may receive the information related to setting the latencies and the information related to the moments when the write and read commands are applied from the module controller 210 through the buffer communication bus BCOM<0:3>.

As described above, the increase in the capacity of the memory devices 230_0 to 230_7 may increase the load resulting from the increased number of memory chips that are included in the memory devices 230_0 to 230_7 and raise the time delay resulting from the error correction operation of the module controller 210. To solve the concerns of the increased load and time delay, the CAS latency CL of the memory module 200 may have to be set to a long value. However, it is difficult to set the data buffers 220_0 to 220_7 to have a long CAS latency CL and operate with the long CAS latency CL. Although it would otherwise have been difficult or not possible to set the data buffers 220_0 to 220_7 to have a long CAS latency CL and operate with the long CAS latency CL, the module controller 210 makes it possible as will be explained in reference to FIGS. 3 and 4.

FIG. 3 is a block diagram Illustrating the module controller 210 shown in FIG. 2.

Referring to FIG. 3, the module controller 210 may include a buffering circuit 310, an error correction code generation circuit 320, an error correction circuit 330, and a control signal generation circuit 340.

The buffering circuit 310 may buffer the command CMD, the address ADD, and the clock CLK that are transferred from the memory controller 2. The buffering circuit 310 may transfer the buffered command CMD, address ADD, and clock CLK to the memory devices 230_0 to 230_7, and transfer the buffered clock CLK to the data buffers 220_0 to 220_7.

The error correction code generation circuit 320 may generate an error correction code by using a write data transferred from the data buffers 220_0 to 220_7, and transfer the write data and the error correction code to the memory devices 230_0 to 230_7. The write data may be transferred through a first internal data bus DATA_INT1, and the write data and the error correction code may be transferred through a second Internal data bus DATA_INT2.

The error correction circuit 330 may correct an error of a read data based on an error correction code read from the memory devices 230_0 to 230_7, and transfer the error-corrected data to the data buffers 220_0 to 220_7. The read data and the error correction code may be transferred through the second internal data bus DATA_INT2, and the error-corrected read data may be transferred through the first internal data bus DATA_INT1.

The control signal generation circuit 340 may generate control signals for controlling the data buffers 220_0 to 220_7, based on the command CMD and the address ADD, and load the control signals on the buffer communication bus BCOM<0:3>.

The control signal generation circuit 340 may include a command decoding unit 341, a control signal generation unit 342, and a latency control circuit 343. The command decoding unit 341 may decode the command CMD and the address ADD to obtain information that is needed for setting and operation of the data buffers 220_0 to 220_7. For example, the command decoding unit 341 may be able to obtain information related to setting the CAS latency CL, information related to setting the write latency WL, information related to applying the write command, and information related to applying the read command. The command decoding unit 341 may receive not the entire address ADD but some bits of the address ADD, and decode the received bits. The control signal generation unit 342 may transform the decoding result of the command decoding unit 341 into the control signals that are appropriate for the protocol of the buffer communication bus BCOM<0:3>.

The latency control circuit 343 may make the data buffers 220_0 to 220_7 operate substantially with a long CAS latency CL by delaying the moment when the control signals are transferred to the data buffers 220_0 to 220_7 through the buffer communication bus BCOM<0:3> during a read operation.

The latency control circuit 343 may include a delayer 344 and a delay setter 345. The delay setter 345 may set a delay value for the delayer 344. The delayer 344 may delay the control signals which are outputted from the control signal generation unit 342, by the delay value set by the delay setter 345.

When the memory module 200 does not perform a read operation, the delay setter 345 may set the delay value of the delayer 344 to ‘0’. When the memory module 200 performs a read operation, the delay setter 345 may set the delay value of the delayer 344 to equal a difference between a first CAS latency value and a second CAS latency value. The first CAS latency value is a value that is set as the CAS latency CL of the memory module 200, and the second CAS latency value is a value that is set as the CAS latency CL of the data buffers 220_0 to 220_7. The delay setter 345 may figure out whether the memory module 200 is performing a read operation or not based on a read signal RD that is enabled by the command decoding unit 341 during a read operation. Although FIG. 3 illustrates an example that the latency control circuit 343 is provided between the command decoding unit 341 and the control signal generation unit 342, the latency control circuit 343 may be disposed behind the control signal generation unit 342. In other words, the latency control circuit 343 may be disposed at any point on the route where the control signals transferred through the buffer communication bus BCOM<0:3> are generated.

FIG. 4 is a table showing an operation of the latency control circuit 343 shown in FIG. 3. FIG. 4 shows how the CAS latency CL of the memory module 200 and the CAS latency CL of the data buffers 220_0 to 220_7 are set according to a combination of bits A12, A6, A5, A4 and A2 of the address ADD, and how the delay setter 345 sets the delay value of the delayer 344. For reference, the CAS latency CL of the memory module 200 may correspond to the first CAS latency value, and the CAS latency CL of the data buffers 220_0 to 220_7 may correspond to the second CAS latency value.

In the illustrated example, among the address ADD bits, the twelfth, sixth, fifth, fourth, and second bits A12, A6, A5, A4 and A2 are used to set the CAS latency CL. When the command CMD including a mode register set (MRS) command for setting the CAS latency CL is applied from the memory controller 2, the CAS latency CL of the memory module 200 may be set based on a combination of the twelfth, sixth, fifth, fourth, second bits A12, A6, A5, A4 and A2 of the address ADD. When the MRS command for setting the CAS latency CL and the combination of the twelfth, sixth, fifth, fourth, second bits A12, A6, A5, A4 and A2 of the address ADD may be transferred to the data buffers 220_0 to 220_7 through the buffer communication bus BCOM<0:3>, the CAS latency CL for the data buffers 220_0 to 220_7 may be set based thereon.

Referring to FIG. 4, based on the combination of the twelfth, sixth, fifth, fourth, second bits A12, A6, A5, A4 and A2 of the address ADD, the CAS latency CL of the memory module 200 may be set to a value of approximately 100 to 146 clock cycles, and the CAS latency CL for the data buffers 220_0 to 220_7 may be set to a value of approximately 9 to 32 clock cycles. This means that the CAS latency CL ranging from approximately 9 to 32 clock cycles is needed for setting and operation of the data buffers 220_0 to 220_7. To complement a difference between the value of the CAS latency CL of the memory module 200, which ranges from approximately 100 to 146, and the value of the CAS latency CL, which ranges from approximately 9 to 32 clock cycles, the latency control circuit 343 may delay the control signals that are supposed to be loaded on the buffer communication bus BCOM<0:3>, by the difference therebetween.

FIG. 4 shows delay values of the latency control circuit 343. For example, when the value of the CAS latency CL of the memory module 200 is set to 100 and the CAS latency CL of the data buffers 220_0 to 220_7 is set to 14, the latency control circuit 343 may delay the control signals by 96. In this case, during a read operation, the data buffers 220_0 to 220_7 may operate with the CAS latency CL of 14 but it receives the control signals that are delayed by 96, it may be able to operate as if the CAS latency CL is 110. In short, although the data buffers 220_0 to 220_7 performs an operation of outputting a data after 14 clock cycles passes from a moment when a read command is applied, since the control signals for informing the data buffers 220_0 to 220_7 of the moment when the read command is applied are transferred to the data buffers 220_0 to 220_7 after being delayed by 96 clock cycles, the data buffers 220_0 to 220_7 may be able to output the data after 110 clock cycles passes from the moment when the read command is applied.

According to the embodiments of the present invention, a memory module can reliably perform an operation with a long latency.

While the present invention has been described with respect to the specific embodiments, it will be apparent to those skilled in the art that various changes and modifications may be made without departing from the spirit and scope of the invention as defined in the following claims.

What is claimed is:

1. A memory module, comprising:
a plurality of memory devices;
a plurality of data buffers suitable for receiving a write data transferred from a memory controller, and transferring a read data to the memory controller; and
a module controller suitable for:
controlling the plurality of the memory devices and the plurality of the data buffers under a control of the memory controller; and,
during a read operation, transferring one or more control signals to the plurality of the data buffers through a buffer communication bus after delaying the control signals by a difference between a first column address strobe (CAS) latency value, which is a set value of the memory module, and a second CAS latency value, which is a set value of the plurality of the data buffers.

2. The memory module of claim 1, wherein the module controller transfers a command, an address, and a clock, which are transferred from the memory controller, to the plurality of the memory devices, and
the module controller generates an error correction code based on the write data that is transferred from the plurality of the data buffers, transfers the write data and the error correction code to the plurality of the memory devices, corrects an error of the read data which is read from the plurality of the memory devices based on the error correction code which is read from the plurality of the memory devices to produce an error-corrected read data, and transfers the error-corrected read data to the plurality of the data buffers.

3. The memory module of claim 1, wherein the module controller includes:
a command decoding unit suitable for decoding a command which is transferred from the memory controller to produce a decoding result;
a control signal generation unit suitable for transforming the decoding result of the command decoding unit into the control signals; and
a latency control circuit suitable for, during the read operation, delaying a moment when the control signals are transferred through the buffer communication bus by the difference between the first CAS latency value and the second CAS latency value.

4. The memory module of claim 3, wherein the latency control circuit includes:
a delayer; and
a delay setter suitable for setting a delay value of the delayer to the difference between the first CAS latency value and the second CAS latency value during the read operation, and setting the delay value of the delayer to ‘0’ during an operation except for the read operation.

5. The memory module of claim 3, wherein the command decoding unit further decodes some bits of an address which is transferred from the memory controller.

6. The memory module of claim 3, wherein the module controller further includes:
an error correction code generation circuit suitable for generating an error correction code based on the write data which is transferred from the plurality of the data buffers; and
an error correction circuit suitable for correcting an error of the read data which is read from the plurality of the memory devices based on the error correction code which is read from the plurality of the memory devices.

7. The memory module of claim 1, wherein, when the memory controller transfers a command and an address for setting a CAS latency to the module controller, a CAS latency of the memory module is set to the first CAS latency value and a CAS latency of the plurality of the data buffers is set to the second CAS latency value, which is different from the first CAS latency value.

8. The memory module of claim 1, wherein each of the plurality of the memory devices is a dynamic random access memory (DRAM), and
the memory module is of a dual in-line memory module (DIMM) type.

9. A memory system, comprising:
a memory module; and
a memory controller suitable for transferring a command, an address, and a write data to the memory module, and receiving a read data from the memory module,
wherein the memory module comprises:
a plurality of memory devices;
a plurality of data buffers suitable for receiving the write data from the memory controller, and transferring the read data to the memory controller; and
a module controller suitable for:
controlling the plurality of the memory devices and the plurality of the data buffers under a control of the memory controller, and,
during a read operation, transferring one or more control signals to the plurality of the data buffers through a buffer communication bus after delaying the control signals by a difference between a first column address strobe (CAS) latency value, which is a set value of the memory module, and a second CAS latency value, which is a set value of the plurality of the data buffers.

10. The memory system of claim 9, wherein the module controller transfers the command, the address, and a clock, which are transferred from the memory controller, to the plurality of the memory devices, and
the module controller generates an error correction code based on the write data that is transferred from the plurality of the data buffers, transfers the write data and the error correction code to the plurality of the memory devices, corrects an error of the read data which is read from the plurality of the memory devices based on the error correction code which is read from the plurality of the memory devices to produce an error-corrected read data, and transfers the error-corrected read data to the plurality of the data buffers.

11. The memory system of claim 9, wherein the module controller includes:
a command decoding unit suitable for decoding the command to produce a decoding result;
a control signal generation unit suitable for transforming the decoding result of the command decoding unit into the control signals; and
a latency control circuit suitable for, during the read operation, delaying a moment when the control signals are transferred through the buffer communication bus by the difference between the first CAS latency value and the second CAS latency value.

12. The memory system of claim 11, wherein the latency control circuit includes:
a delayer; and
a delay setter suitable for setting a delay value of the delayer to the difference between the first CAS latency value and the second CAS latency value during the read operation, and setting the delay value of the delayer to ‘0’ during an operation except for the read operation.

13. The memory system of claim 11, wherein the command decoding unit further decodes some bits of the address.

14. The memory system of claim 11, wherein the module controller further includes:
an error correction code generation circuit suitable for generating an error correction code based on the write data which is transferred from the plurality of the data buffers; and
an error correction circuit suitable for correcting an error of the read data which is read from the plurality of the memory devices based on the error correction code which is read from the plurality of the memory devices.

15. The memory system of claim 9, wherein when the memory controller transfers the command and the address for setting a CAS latency to the module controller, a CAS latency of the memory module is set to the first CAS latency value and a CAS latency of the plurality of the data buffers is set to the second CAS latency value, which is different from the first CAS latency value.

16. The memory system of claim 9, wherein each of the plurality of the memory devices is a dynamic random access memory (DRAM), and the memory module may be of a dual in-line memory module (DIMM) type.
